(19) United States
(12) Patent Application Publication
(10) Pub. No.: US 2013/0154111 A1
(43) Pub. Date: Jun. 20, 2013

(54) SEMICONDUCTOR DEVICE INCLUDING THROUGH ELECTRODE AND METHOD OF MANUFACTURING THE SAME AND STACKED PACKAGE INCLUDING SEMICONDUCTOR DEVICE AND METHOD OF MANUFACTURING THE SAME

(71) Applicant: Sang Jin BYEON, Ichon-si (KR)

(72) Inventor: Sang Jin BYEON, Ichon-si (KR)

(73) Assignee: HYNIX SEMICONDUCTOR, INC., Icheon-si (KR)

(21) Appl. No.: 13/445,736

(22) Filed: Apr. 12, 2012

(30) Foreign Application Priority Data
Dec. 15, 2011 (KR) 10-2011-0135700

(51) Int. Cl. H01L 23/538; H01L 21/50; H01L 21/768

(52) U.S. Cl. 257/774; 438/667; 438/107; 257/E23.174; 257/E21.499; 257/E21.597

(57) ABSTRACT

A semiconductor device including a wafer having an upper surface and a lower surface, circuit layers formed on the upper surface and the lower surface of the wafer, respectively, and a through electrode formed to penetrate the wafer is presented. The through electrode can be configured to electrically coupled the circuit layers formed on the upper surface and the lower surface of the wafer. The semiconductor device can be stacked to form a stacked package.

### CROSS-REFERENCES TO RELATED APPLICATION

The present application claims priority under 35 U.S.C. 119(a) to Korean application number 10-2011-0135700, filed on Dec. 15, 2011, in the Korean Patent Office, which is incorporated herein by reference in its entirety.

### BACKGROUND OF THE INVENTION

1. Field of the Invention

Embodiments of the present invention relate to a semiconductor package and a method of manufacturing the same, and more particularly, to a semiconductor device including a through electrode and a stacked package including the semiconductor device.

2. Discussion of Related Art

In recent years, capacity and speed of semiconductor memories used as storage devices in most electronic systems has been increasing. In addition, various attempts have been made to mount a large capacity of memories in a smaller area and to drive the mounted memories efficiently.

To improve the degree of integration of semiconductor packages, three dimensional arrangement technology in which a plurality of memory chips are stacked has begun to be applied in place of existing planar arrangement technologies.

Three dimensional arrangement technology has been employed in the semiconductor packaging field. Research on through silicon vias (TSVs), which are formed to penetrate chips to interface between stacked semiconductor chips, has progressed.

TSVs are formed to penetrate semiconductor substrates (chips) in which circuit layers are formed on one surface thereof and serve to connect the semiconductor substrates (chips) that are vertically stacked. TSVs are referred to as through electrodes.

Currently, semiconductor packages employing TSVs require a small area, a thin thickness, and low power consumption of individual chips that are connected to each other. Therefore, there is a need for better through electrodes for vertically stacking chips.

### SUMMARY

According to one aspect of an exemplary embodiment, a semiconductor device is provided. A semiconductor device according to some embodiments includes a wafer having an upper surface and a lower surface; circuit layers formed on each of the upper surface and the lower surface of the wafer; and a through electrode formed to penetrate the wafer and configured to electrically couple the circuit layers formed on the upper surface and the lower surface of the wafer.

According to another aspect of an exemplary embodiment, a stacked package is provided. The stacked package includes a plurality of stacked semiconductor devices. Each of the semiconductor devices includes circuit layers formed on an upper surface and a lower surface of a wafer, and a through electrode formed through the wafer and configured to electrically coupled the circuit layers.

According to still another aspect of an exemplary embodiment, a method of manufacturing a semiconductor device is provided. The method includes providing a wafer having a top surface and a bottom surface, forming an upper circuit layer on the top surface of the wafer, processing the bottom surface of the wafer, forming a through electrode connected to the upper circuit layer through the bottom surface of the wafer, and forming a lower circuit layer on the bottom surface of the wafer at both sides of the through electrode.

According to yet another aspect of an exemplary embodiment, a method of manufacturing a stacked package is provided. The method includes providing semiconductor devices, each of the semiconductor devices including circuit layers formed on an upper surface and a lower surface of a wafer and a through electrode penetrating the wafer, and mounting the semiconductor devices to be stacked.

These and other features, aspects, and embodiments are described below with reference to the following figures.

### BRIEF DESCRIPTION OF THE DRAWINGS

Aspects, features and other advantages of embodiments of the present disclosure will be more clearly understood from the following detailed description taken in conjunction with the accompanying drawings, in which:

FIG. 1 illustrates a schematic of an exploded perspective view illustrating a stacked package including a semiconductor device according to some embodiments of the invention;

FIGS. 2A to 2F illustrate cross-sectional views for processes of a method of manufacturing a semiconductor device according to some embodiments of the invention;

FIGS. 3, 4 and 9 illustrate cross-sectional views illustrating a method of manufacturing a semiconductor device according to some embodiments of the invention;

FIG. 5 illustrates a cross-sectional view illustrating a stacked package according to some embodiments of the invention;

FIG. 6 illustrates a cross-sectional view of a stacked package according to some embodiments of the invention; and

FIGS. 7 and 8 illustrate circuit diagrams of a noncontact communication unit built into a stacked package according to some embodiments of the invention.

In the figures, elements having the same designation have the same or similar functions.

### DETAILED DESCRIPTION

Hereinafter, exemplary embodiments will be described in greater detail with reference to the accompanying drawings. In the following description specific details are set forth describing certain embodiments. It will be apparent, however, to one skilled in the art that the disclosed embodiments may be practiced without some or all of these specific details. The specific embodiments presented are meant to be illustrative, but not limiting. One skilled in the art may realize other material that, although not specifically described herein, is within the scope and spirit of this disclosure.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limiting the particular shapes of regions illustrated herein, which may include deviations in shapes that result, for example, from manufacturing. In the drawings, lengths and sizes of layers and regions may be exaggerated for clarity. Like reference numerals in the drawings denote like elements. It is also understood that when a layer is referred as being “on” another layer or substrate, it can be directly on the other or substrate, or intervening layers may also be present. Further, indications of directionality such as over, under, top, bottom, higher, lower, or other expression is not absolute and is meant to indicate relative relationships only, embodiments may be placed in any orientation.

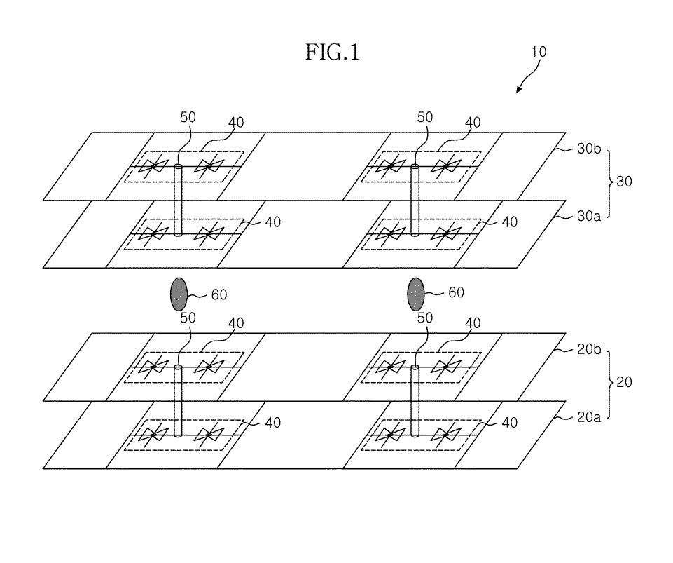

FIG. 1 illustrates a perspective view illustrating a semiconductor device including stacked wafers 20 and 30 before sawing according to some embodiments. Referring to FIG. 1, a semiconductor device 10 includes a plurality of stacked wafers, of which wafers 20 and 30 are illustrated. There may be any number of wafers stacked in semiconductor device 10. Each of the plurality of stacked wafers 20 and 30 has a lower surface 20a and 30a and an upper surface 20b and 30b, respectively. Circuit layers 40 are formed on the lower surface 20a and 30a and on the upper surface 20b and 30b, respectively. A through electrode 50, which is configured to electrically couple the circuit layers 40 formed on the upper surfaces 20b and 30b with the circuit layers 40 formed on lower surfaces 20a and 30a, respectively, of each wafer 20 and 30 is formed within each of the wafers 20 and 30. The stacked wafers 20 and 30 can be electrically coupled to each other by a connection terminal 60, which can couple electrode 50 of wafer 20 with electrode 50 of wafer 30.

In the semiconductor device 10 of the exemplary embodiment, since the circuit layers 40 are formed on both sides of each wafer 20 and 30, one piece of wafer serves as two pieces of existing wafer so that a large number of circuits can be integrated while realizing a reduction in package height.

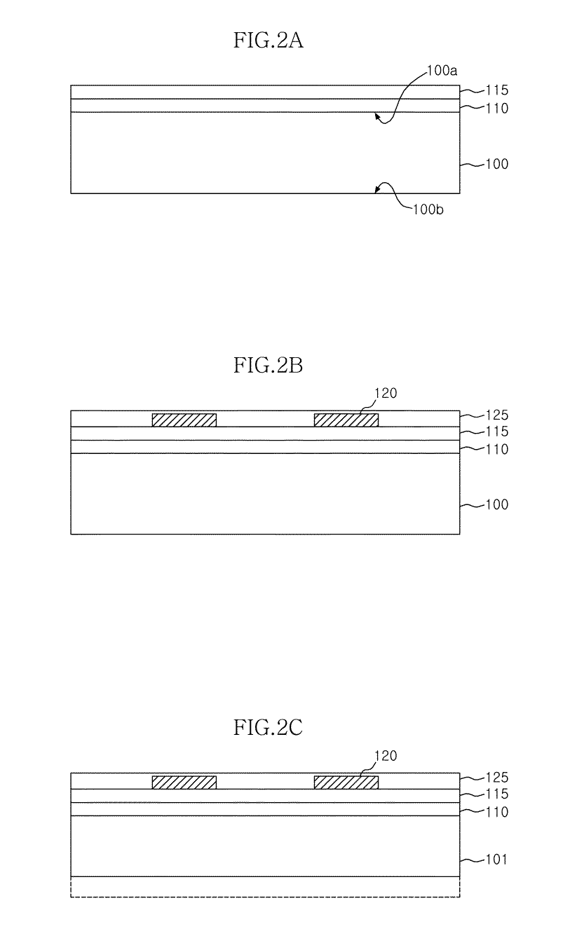

Hereinafter, a method of manufacturing a semiconductor device according to some embodiments will be described with reference to FIGS. 2A to 2F. In the exemplary embodiment, a method of manufacturing one piece of wafer constituting the semiconductor device will be described. It is understood that multiple such wafers can be formed and interconnected as illustrated in FIG. 1.

First, referring to FIG. 2A, a bare wafer 100 having an upper (top) surface 100a and a lower (bottom) surface 100b is prepared. A first circuit layer 110 is formed on the upper surface 100a of the wafer 100. The first circuit layer 110 may be a layer formed by a front end process (e.g., formation of semiconductor devices in the silicon) and be a multi-layered structure including circuit devices. A second circuit layer 115 can be formed on the first circuit layer 110. The second circuit layer 115 may be a layer formed by a back end process (e.g., formation of metallization and interconnect layers) and be a multi-layered structure including circuit devices or a protection layer.

Referring to FIG. 2B, an upper bump pad 120 is formed on the second circuit layer 115. The upper bump pad 120 may be disposed in a portion of the second circuit layer 115 in which a through electrode is to be later formed. A supporting layer 125 is formed on an upper surface of the second circuit layer 115 in which the upper bump pad 120 is formed. The supporting layer 125 may be a layer in which an adhesion layer, an auxiliary insulating layer, and a peeling tape are stacked.

Referring to FIG. 2C, a predetermined thickness of the bottom surface 100b of the wafer 100 is removed, for example by grinding, using the supporting layer 125 as a fixing member, thereby fabricating a planar surface in which further circuit layers can be formed. The reference numeral 101 denotes a wafer 100 with the predetermined thickness removed from the bottom.

Referring to FIG. 2D, a through hole (not shown) is formed from the bottom of the wafer 101 to expose the upper bump pad 120. An insulating layer 130 is then deposited on a sidewall surface of the through hole and a conductive material is provided to fill the through hole to form a through electrode 135. Electrode 135 is then, for example, a through silicon via (TSV) 135.

Referring to FIG. 2E, a third circuit layer 140 is formed in the bottom of wafer 101 at both sides of the through electrode 135 by a front end process and a fourth circuit layer 145 is formed by a back end process. A lower bump pad 150 is formed on the fourth circuit layer 145 to be in electrical connection with the through electrode 135. The upper bump pad 120 and the lower bump pad 150 can be electrically coupled to connection terminals 60 (FIG. 1), which is configured to electrically couple through electrodes of wafers 20 and 30 which are to be vertically stacked. Here, although not shown in detail, the first to fourth circuit layers 110, 115, 140, and 145 may be electrically insulated from the through electrode 135.

Referring to FIG. 2F, wafer 101 in which the circuit layers 110, 115, 140 and 145 are formed on both surfaces thereof, for example, is scribed and sawed to separate each semiconductor device D, which is an individual chip. The reference numeral S denotes a sawing region.

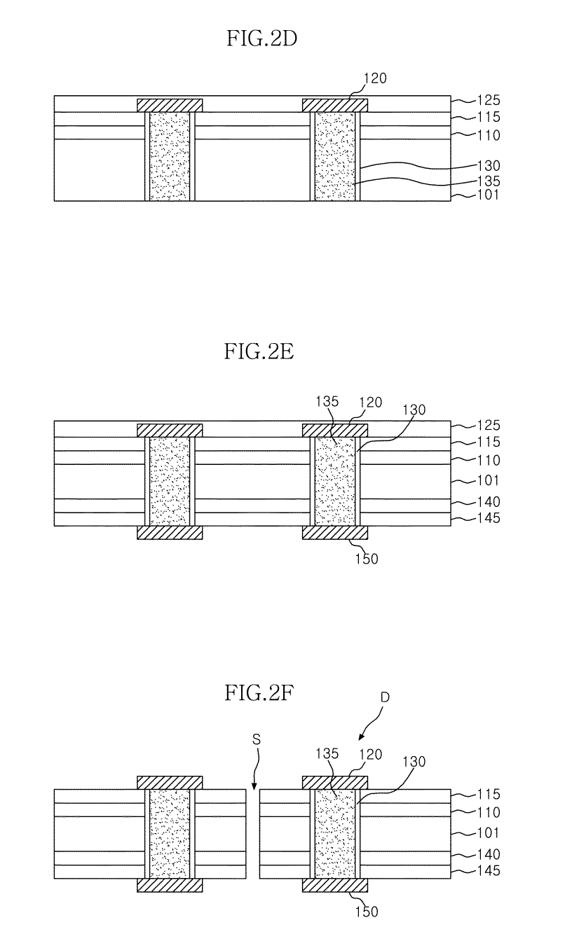

Alternatively, as shown in FIG. 3, a through electrode 135 can formed within a bare wafer 100 or a ground wafer 101 (as shown in FIG. 9) before deposition of any circuit layers. The circuit layers may be formed on an upper surface 100a and a lower surface 100b of the wafer 100 (or ground wafer 101). Then, as shown in FIG. 9, the upper and lower pads 120 and 150 are formed on the second and fourth circuit layers 110 and 145, respectively. At that time, the through electrode 135 is electrically coupled with the upper and lower pads 120 and 150 by conductive members(not shown) which are formed in the first to fourth circuit layers 110, 115, 140, and 145, for example, metal interconnections.

As shown in FIG. 4, a through electrode may be formed from the upper surface of wafer 101 and from the lower surface of wafer 101, causing the electrode to be divided into an upper portion and a lower portion on the basis of a center of the wafer 101. That is, an upper through electrode 136 having a constant depth is formed from an upper surface of the wafer 101 and a lower through electrode 142, which is electrically coupled to the upper through electrode 136, is formed from the lower surface of the wafer 101. Insulating layers 131 and 141 are interposed between the upper and lower through electrodes 136 and 142 and the wafer 101, respectively.

A first circuit layer 110 may be formed at the both sides of the upper through electrode 136 and a second circuit layer 116 may be formed on the upper through electrode 110 and the first circuit layer 110. At this time, a portion of the second circuit layer 116, which overlaps the upper through electrode 136, may be formed of a conductive material so that the portion of the second circuit layer 116 may transmit a signal to the upper through electrode 136, which is electrically insulated from the first circuit layer 110 disposed at both sides of the upper through electrode 136. Upper through electrode 136 is electrically coupled to upper pads 120 through second circuit layer 116 and lower electrode 142 is electrically coupled to lower pad 150 through second circuit layer 145.

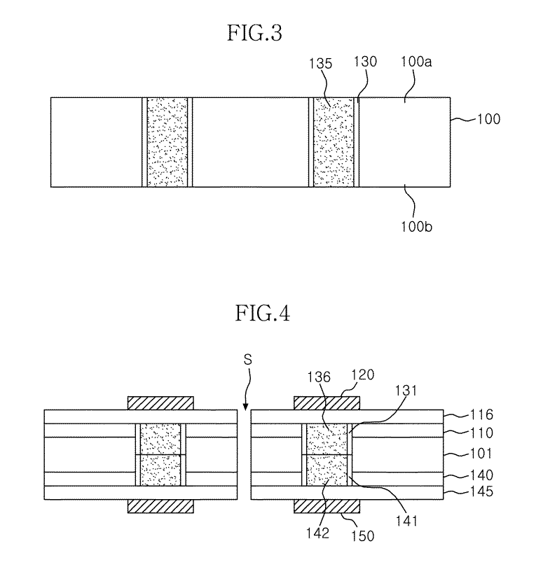

As shown in FIG. 5, a plurality of semiconductor devices D1 to Dn+1 may be stacked on a printed circuit board (PCB) 200 in which an external connection terminal 210 is formed on a bottom surface thereof. The stacked semiconductor devices D1 to Dn+1 may be electrically coupled to each other by connection terminals 160 such as bumps. The connection terminal 160 may be disposed between through electrodes 135 of the stacked semiconductor devices D1 to Dn+1. Alternatively, in certain regions of the semiconductor devices D1 to Dn+1, connection terminals 160 may coupled to other areas of semiconductor devices D1 to Dn+1 by a redistribution manner. Further, semiconductor device D1 can be electrically coupled to circuit board 200 through connection terminals 165.

In addition, each of the semiconductor devices D1 to Dn+1 according to some embodiments may include a noncontact communication unit 180. As the noncontact communication unit 180, as shown in FIG. 5, first and second communication units 180a and 180b may be built into the upper surface and the lower surface, respectively, of wafers D1 to Dn+1. The first and second communication units 180a and 180b may be stackably arranged to be spaced apart at a specific distance, thereby allowing signals to be received from one to another. In FIG. 5, the reference numeral 165 may denote a connection terminal configured to electrically connect the semiconductor devices D1 to Dn+1 and the PCB 200.

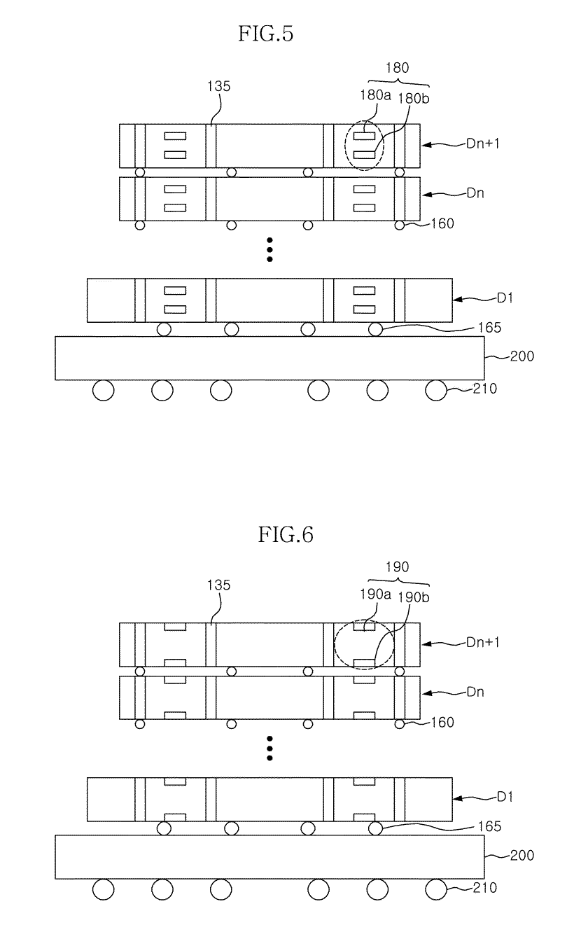

Alternatively, as shown in FIG. 6, a first communication unit 190a may be disposed in an upper surface of each of semiconductor devices D1 to Dn+1 and a second communication unit 190b may be disposed on a lower surface of each of the semiconductor devices D1 to Dn+1. However, embodiments are not limited to this arrangement. The communication unit may be variously disposed in any position in which a signal is received from one another.

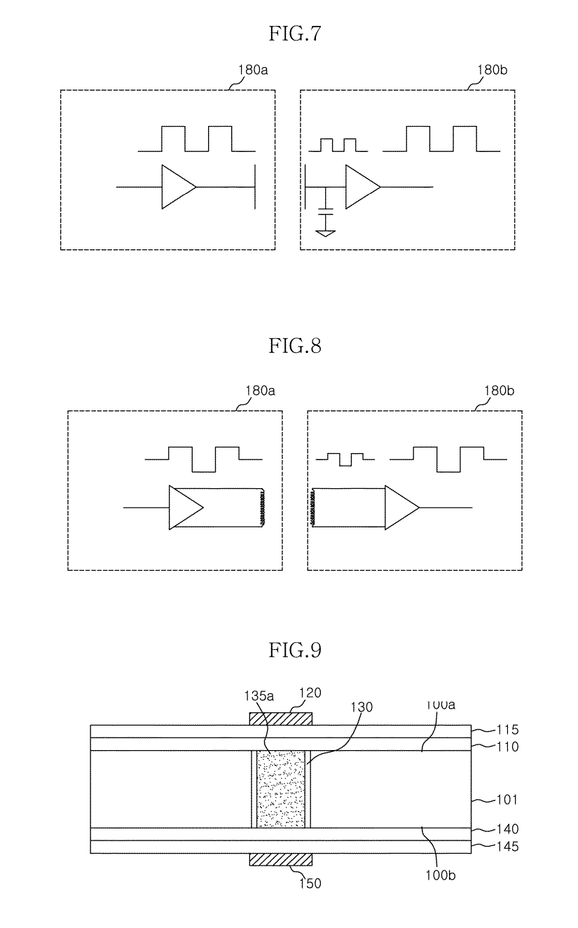

The noncontact communication units 180a and 180b, and 190a and 190b may have a capacitive coupling structure as shown in FIG. 7, or an inductive capacitive coupling structure as shown in FIG. 8.

The noncontact communication units enable noncontact communication between upper and lower circuit layers of each semiconductor device and between circuit layers of adjacent semiconductor devices.

As described above, according to the exemplary embodiment, circuit layers are formed on upper and lower surfaces of a wafer having a through electrode to fabricate a semiconductor device including the circuit layers on both surfaces thereof. Therefore, since one piece of a wafer serves as two pieces of existing wafers when a stacked package is implemented, a large number of circuits can be integrated with reduction in a package height.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A semiconductor device, comprising:
a wafer having an upper surface and a lower surface;
circuit layers formed on each of the upper surface and the lower surface of the wafer; and
a through electrode formed to penetrate the wafer and configured to electrically couple the circuit layers formed on the upper surface and the lower surface of the wafer.

2. The semiconductor device of claim 1, wherein the through electrode includes:
an upper through electrode disposed adjacent to the upper surface of the wafer; and
a lower through electrode electrically connected to the upper through electrode and disposed adjacent to the lower surface of the wafer.

3. The semiconductor device of claim 1, further comprising:
an upper bump pad formed on the upper surface of the wafer and electrically coupled to the through electrode; and
a lower bump pad formed on the lower surface of the wafer and electrically coupled to the through electrode.

4. The semiconductor device of claim 1, further comprising an insulating layer between the through electrode and the wafer.

5. The semiconductor device of claim 1, further including noncontact communication units.

6. The semiconductor device of claim 5, wherein the noncontact communication units are capacitively coupled.

7. The semiconductor device of claim 5, wherein the noncontact communication units are inductively coupled.

8. A stacked package, comprising:
a plurality of stacked, electrically coupled semiconductor devices,
each of the semiconductor devices including:
circuit layers formed on an upper surface and a lower surface of a wafer; and
a through electrode formed through the wafer and configured to electrically couple the circuit layers.

9. The stacked package of claim 8, further comprising a plurality of connection terminals disposed between the stacked semiconductor devices and electrically coupling the stacked semiconductor devices.

10. The stacked package of claim 9, wherein the connection terminals are disposed between through electrodes of vertically adjacent semiconductor devices.

11. The stacked package of claim 9, wherein the semiconductor device further includes a bump pad electrically coupled to the through electrode and positioned between the through electrode and a corresponding one of the connection terminals.

12. The stacked package of claim 8, wherein the through electrode includes:
an upper through electrode disposed adjacent to the upper surface of the semiconductor device; and
a lower through electrode electrically connected to the upper through electrode and disposed adjacent to the lower surface of the semiconductor device.

13. The stacked package of claim 8, further comprising a printed circuit board on which the stacked semiconductor devices are mounted.

14. The stacked package of claim 13, further comprising a plurality of external connection terminals disposed on a bottom surface of the printed circuit board.

15. The stacked package of claim 8, wherein each of the semiconductor devices further includes a noncontact communication unit configured to communicate between the circuit layers formed on the upper and lower surfaces thereof and between circuit layers of adjacent semiconductor devices.

16. The stacked package of claim 15, wherein the noncontact communication unit has one of a capacitive coupling structure and an inductive capacitive coupling structure.

17. The stacked package of claim 11, wherein the semiconductor device further includes an insulating layer interposed between the through electrode and the semiconductor device.

18. A method of manufacturing a semiconductor device, comprising:
providing a wafer having a top surface and a bottom surface;
forming an upper circuit layer on the upper surface of the wafer;
processing the bottom surface of the wafer;
forming a through electrode from and through the rear surface of the wafer to be connected to the upper circuit layer; and
forming a lower circuit layer on the bottom surface of the wafer at both sides of the through electrode.

19. The method of claim 18, wherein processing the bottom surface of the wafer includes grinding the bottom surface of the wafer by a predetermined thickness.

20. The method of claim 18, wherein forming the through electrode includes:
forming a through hole in the side of the wafer; and
forming an insulating layer on a sidewall of the through hole.

21. A method of manufacturing a stacked package, comprising:
providing semiconductor devices, each of the semiconductor devices including circuit layers formed on an upper surface and a lower surface of a wafer and a through electrode penetrating the wafer; and
mounting the semiconductor devices to be stacked.

22. A method of manufacturing a stackable semiconductor device, comprising:
forming a through electrode through a wafer;
forming circuit layers on an upper side of the wafer and on a bottom side of the wafer.

23. The method of claim 22, wherein forming the through electrode includes forming an upper electrode from the upper side of the wafer and forming a bottom electrode from the bottom side of the wafer.

24. The method of claim 22, further including forming pads that are electrically coupled to the through electrode on the upper side of the wafer and the lower side of the wafer.
